(19) United States
(12) Patent Application Publication
(10) Pub. No.: US 2026/0342339 A1
(43) Pub. Date: Oct. 29, 2026

(54) DEVICES AND METHODS THEREOF FOR AUTOMATICALLY ACTIVATING PHASE-LOCKED LOOP OF ANALOG-FRONT-END DEVICE

(71) Applicant: MediaTek Singapore Pte. Ltd., Singapore (SG)

(72) Inventors: Junyan LI, Shenzhen (CN); Jing-Lin KUO, Hsinchu City (TW); Jie WANG, Shenzhen (CN)

(21) Appl. No.: 19/211,531

(22) Filed: May 19, 2025

(30) Foreign Application Priority Data
Apr. 23, 2025 (CN) 202510523495.4

(51) Int. Cl. H03L 7/08

(52) U.S. Cl. CPC H03L 7/08

(57) ABSTRACT

An analog-front-end device is provided, which includes, a phase-locked loop, a first register, an analog-to-digital converter, and a controller. The phase-locked loop is activated based on a clock enable signal to generate a clock signal. The first register stores first data related to the analog signal based on the clock signal. The analog-to-digital converter converts the analog signal to the first data based on the clock signal. The controller determines whether the phase-locked loop is activated based on a flag to generate the clock enable signal, and operates in a sampling mode based on a first instruction. When the controller operates in the sampling mode, the controller activates the phase-locked loop using the clock enable signal. When the controller exits the sampling mode, the controller deactivates the phase-locked loop.

### CROSS REFERENCE TO RELATED APPLICATIONS

This Application claims priority of China Patent Application No. 202510523495.4, filed on Apr. 23, 2025, the entirety of which is incorporated by reference herein.

### BACKGROUND OF THE INVENTION

### Field of the Invention

The disclosure is generally related to devices and methods thereof for automatically activating a phase-locked loop of an analog-front-end device operating in the low-power mode.

### Description of the Related Art

In general, an analog-front-end device always stays in low-power mode and only activates to sample signals, so as to minimize its power consumption and to extend battery life. In addition, a precise clock is required for accurate sampling, so that a phase-locked loop is required. However, a phase-locked loop is hugely power consuming, leading to greatly shortening the battery life. Therefore, it is important to activate and deactivate the phase-locked loop at the right time.

A phase-locked loop of the analog-front-end device is usually activated or deactivated by a remote MCU (or, a host) through the communication interface. When the MCU executes multi-threading, the command to activate or deactivate the phase-locked loop may be conflicting to other commands. When the phase-locked loop is not activated in time, the data read from the register of the analog-front-end device may be wrong. When the phase-locked loop is not deactivated in time, more power is consumed, leading to shortening the battery life.

### BRIEF SUMMARY OF THE INVENTION

Analog-front-end devices and methods thereof are provided herein. The analog-front-end devices provided herein are able to wake up from the low-power mode to the sampling mode or the access mode by using the methods provided herein. In addition, the analog-front-end devices are also able to return to the low-power mode when the sampling mode or the access mode is completed. Moreover, a flag indicating whether the phase-locked loop is activated is provided. It is much convenient for the analog-front-end devices to determine whether the phase-locked loop is activated by monitoring the flag.

In an embodiment, an analog-front-end device comprises, a phase-locked loop, a first register, an analog-to-digital converter, and a controller. The phase-locked loop is activated based on a clock enable signal to generate a clock signal. The first register stores first data related to an analog signal based on the clock signal. The analog-to-digital converter retrieves setting parameters from the first register based on the clock signal and converts the analog signal to the first data based on the clock signal. The controller determines whether the phase-locked loop is activated based on a flag to generate the clock enable signal and operates in a sampling mode based on a first instruction. When the controller operates in the sampling mode, the controller activates the phase-locked loop using the clock enable signal. When the controller exits the sampling mode, the controller deactivates the phase-locked loop.

According to an embodiment of the present invention, the electronic circuit further comprises a second register. The second register stores the flag indicating whether the phase-locked loop is activated. When the flag is set to a first level, the phase-locked loop is activated. When the flag is set to a second level, the phase-locked loop is deactivated.

According to an embodiment of the present invention, before the controller activates the phase-locked loop, the controller determines whether the phase-locked loop is activated by determining whether the flag is set to a first level.

According to an embodiment of the present invention, the analog-front-end device further comprises a timer. The timer counts a delay time based on an idle signal and generating a clock disable signal when the delay time reaches a predetermined period. When the first register is idle, the controller triggers the idle signal to trigger the timer to count the delay time. When the delay time reaches the predetermined period, the timer triggers the clock disable signal to deactivate the phase-locked loop and to set the flag to the second level.

According to an embodiment of the present invention, the setting parameters comprise a pulse repetition period, a sampling period of the sampling mode, offset error, full-scale error, differential nonlinearity (DNL), and integral nonlinearity (INL). The pulse repetition period comprises a low-power mode and the sampling mode.

According to an embodiment of the present invention, the analog-front-end device further comprises an interface. The interface receives the first instruction from a host. When the interface receives the first instruction, the interface provides the first instruction to the controller.

According to an embodiment of the present invention, when the host transmits a second instruction to access the first data in the first register, the controller operates in an access mode. When the controller operates in the access mode, the controller activates the phase-locked loop. Before the phase-locked loop is activated, the controller checks the flag to determine whether the phase-locked loop is activated. When the flag indicates that the phase-locked loop is deactivated, the controller activates the phase-locked loop. The first data in the first register and the clock signal are provided to the host through the interface.

According to an embodiment of the present invention, the controller periodically operates in the sampling mode, and occasionally operates in the access mode based on the second instruction being received.

According to an embodiment of the present invention, the first instruction defines a pulse repetition period and a duty period of the sampling mode in the pulse repetition period. When the controller does not operate the sampling mode during the pulse repetition period, the analog-front-end device operates in a low-power mode to minimize power consumption.

According to an embodiment of the present invention, the access mode occurs when the controller does not operate in the sampling mode.

In another embodiment, a method for accessing a first register of an analog-front-end device operating in a low-power mode is provided. The analog-front-end device further comprises a phase-locked loop generating a clock signal. The method comprises the following steps. It is determined whether a flag is set to a first level. When the flag is not set to a first level, the phase-locked loop is activated to generate the clock signal. The first register is accessed based on the clock signal.

According to an embodiment of the present invention, the method further comprises the following steps. When the flag is set to a first level, it is determined that the phase-locked loop is activated. When the flag is not set to a first level, it is determined that the phase-locked loop is deactivated and then activating the phase-locked loop.

According to an embodiment of the present invention, the method further comprises the following steps. It is determined whether the first register is idle. When the first register is idle, a delay time is counted. It is determined whether the delay time has reached a predetermined period. When the delay time reaches the predetermined period, the phase-locked loop is deactivated and the flag is set to a second level. When the delay time has not reached the predetermined period, the phase-locked loop is kept activated and the delay time continues to be counted.

According to an embodiment of the present invention, the analog-front-end device further comprises an interface. The method further comprises the following steps. A first instruction is received from a host through the interface. The analog-front-end device is operated in a sampling mode. The phase-locked loop is activated to generate the clock signal in the sampling mode. After the sampling mode, the phase-locked loop and the functional circuit are deactivated. The step of accessing the first register based on the clock signal further comprises the following step. First data related to the analog signal is written into the first register based on the clock signal.

According to an embodiment of the present invention, the analog signal is converted into the first data by an analog-to-digital converter. The first data is a digital data. Setting parameters of the analog-to-digital converter are stored in the first register. The setting parameters comprise a pulse repetition period, a sampling period of the sampling mode, offset error, full-scale error, differential nonlinearity (DNL), and integral nonlinearity (INL). The pulse repetition period comprises a low-power mode and the sampling mode.

According to an embodiment of the present invention, the period of the sampling mode is defined in the first instruction.

According to an embodiment of the present invention, the method further comprises the following steps. A second instruction is received from the host through the interface. The analog-front-end device is operated in an access mode based on the second instruction. The phase-locked loop is activated to generate the clock signal in the access mode. The first data is provided from the first register to the host through the interface. After the access mode, the phase-locked loop and the functional circuit are deactivated. The step of accessing the first register based on the clock signal further comprises the following steps. The first data in the first register is read based on the clock signal.

According to an embodiment of the present invention, the sampling mode is operated periodically, and the access mode is operated occasionally based on the second instruction being received.

According to an embodiment of the present invention, the first instruction defines a pulse repetition period. The analog-front-end device is operated in either the sampling mode or the low-power mode during the pulse repetition period. A duty period of the sampling mode is defined in the first instruction.

According to an embodiment of the present invention, the analog-front-end device is operated in the access mode when the analog-front-end device is not operated in the sampling mode.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a block diagram of an analog-front-end device in accordance with an embodiment of the present invention;

FIG. 2 is a flow chart of a method for accessing a first register of an analog-front-end device in the low-power mode in accordance with an embodiment of the present invention; and

FIG. 3 illustrates operations of an analog-front-end circuit in accordance with an embodiment of the present invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth in order to provide a thorough understanding of the present disclosure. The use of like and/or corresponding numerals in the drawings of different embodiments does not suggest any correlation between different embodiments.

In addition, in some embodiments of the present disclosure, terms concerning attachments, coupling and the like, such as “connected” and “interconnected,” refer to a re-lationship wherein structures are secured or attached to one another either directly or indi-rectly (for example, electrically connection) via intervening structures, as well as both mov-able or rigid attachments or relationships, unless expressly described otherwise.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be consid-ered part of the entire written description. The drawings are not drawn to scale. In addition, structures and devices are shown schematically in order to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a re-lationship wherein structures are secured or attached to one another either directly or indi-rectly (for example, electrically connection) via intervening structures, as well as both mov-able or rigid attachments or relationships, unless expressly described otherwise.

In the drawings, similar elements and/or features may have the same reference number. Various components of the same type can be distinguished by adding letters or numbers after the component symbol to distinguish similar components and/or similar features.

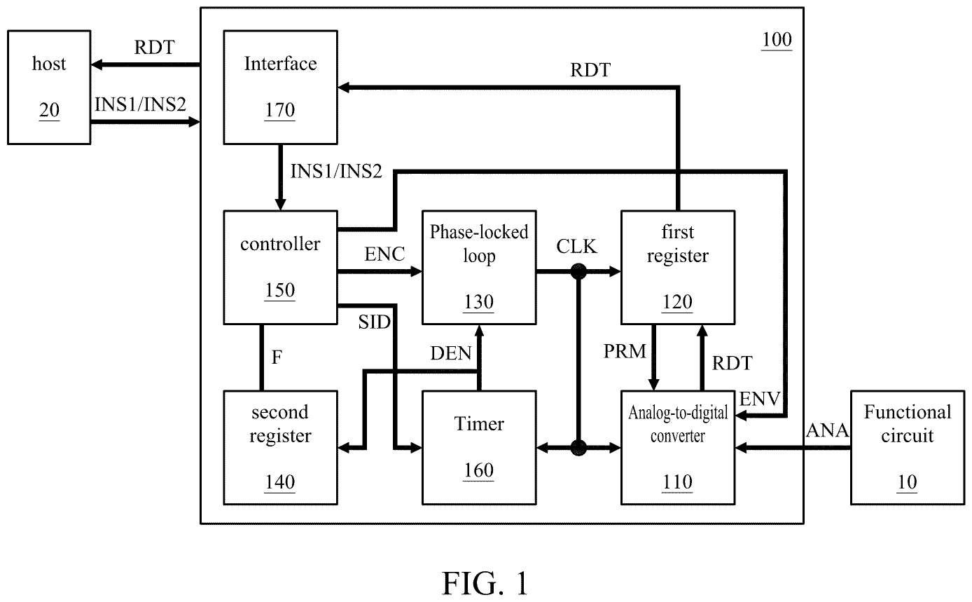

FIG. 1 is a block diagram of an analog-front-end device in accordance with an embodiment of the present invention. As shown in FIG. 1, the analog-front-end device 100 receiving an analog signal ANA from a functional circuit 10 includes an analog-to-digital converter 110, a first register 120, a phase-locked loop 130, a second register 140, a controller 150, and a timer 160.

As shown in FIG. 1, the functional circuit 10 generates the analog signal ANA. According to some embodiments of the present invention, the functional circuit 10 may include a plurality of sensors sensing the environment to generate the analog signal ANA. According to some embodiments of the present invention, the functional circuit 10 may be any type of circuit for generating the analog signal ANA.

The analog-to-digital converter 110 is activated by a conversion enable signal ENV and converts the analog signal ANA from the functional circuit 10 into first data RDT based on the clock signal CLK. According to some embodiments of the present invention, the first data RDT is digital data.

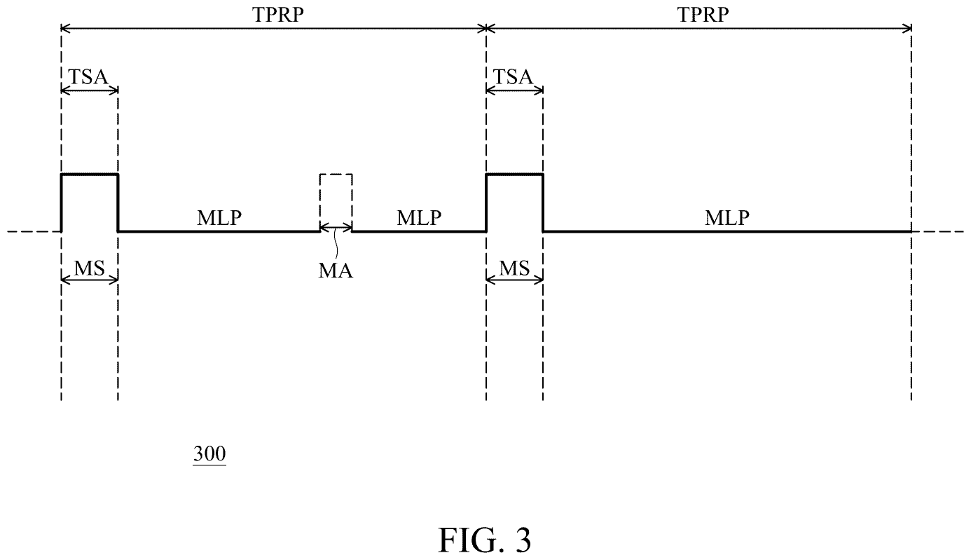

The first register 120 stores the first data RDT generated by the analog-to-digital converter 110 and the setting parameters PRM of the analog-to-digital converter 110. According to some embodiments of the present invention, the setting parameters PRM includes the pulse repetition period TPRP in FIG. 3 (will be described in the following paragraph), the sampling period TSA in FIG. 3 (will be described in the following paragraph), offset error, full-scale error, differential nonlinearity (DNL), and integral nonlinearity (INL) of the analog-to-digital converter 110. According to some embodiments of the present invention, when the first data RDT is read from the first register 120 or written into the first register 120, a clock signal CLK is required. According to some embodiments of the present invention, the analog-to-digital converter 110 retrieves the setting parameters PRM from the first register 120 based on the clock signal CLK.

The phase-locked loop 130 is activated based on a clock enable signal ENC to generate the clock signal CLK, and the analog-to-digital converter 110 and the first register 120 operate based on the clock signal CLK. According to some embodiments of the present invention, when the phase-locked loop 130 is deactivated, the analog-to-digital converter 110 is deactivated.

The second register 140 stores a flag F for indicating whether the phase-locked loop 130 is activated. According to an embodiment of the present invention, when the flag F is set to a first level, it indicates that the phase-locked loop 130 is activated. According to another embodiment of the present invention, when the flag F is set to a second level, it indicates that the phase-locked loop 130 is deactivated. According to some embodiments of the present invention, when the flag F is set to a first level, the flag F is in the high logic level. When the flag F is set to a second level, the flag F is in the low logic level.

The controller 150 generates the clock enable signal ENC to activate/deactivate the phase-locked loop 130, and generates the conversion enable signal ENV to activate the analog-to-digital converter 110 to operate based on the clock signal CLK generated by the phase-locked loop 130. In addition, the controller 150 determines whether the phase-locked loop 130 is activated based on the flag F. In other words, before the controller 150 acti-vates/deactivates the phase-locked loop 130 by using the clock enable signal ENC, the controller 150 determines whether the phase-locked loop 130 is activated by determining whether the flag F is set to a first level.

As shown in FIG. 1, the timer 160 counts a delay time based on an idle signal SID. According to some embodiments of the present invention, when the controller 150 determines that the first register 120 is idle, the controller 150 triggers the idle signal SID to trigger the timer 160 to count the delay time. When the delay time reaches a predetermined period, the timer 160 triggers the clock disable signal DEN to deactivate the phase-locked loop 130, thereby reducing the overall power consumption of the analog-front-end device 100. According to some embodiments of the present invention, the flag F is set to a first level by the clock enable signal ENC, and set to a second level by the clock disable signal DEN.

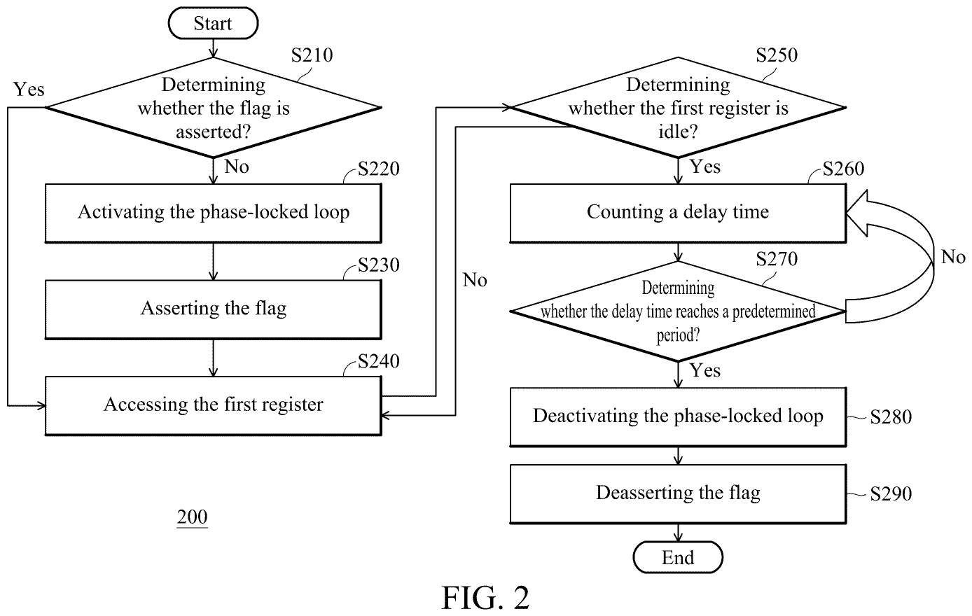

FIG. 2 is a flow chart of a method for accessing a first register of an analog-front-end device in the low-power mode in accordance with an embodiment of the present invention. In the following paragraphs, the method 200 is described in accompanied with the analog-front-end device 100 in FIG. 1 for detailed explanation. According to some embodiments of the present invention, when the analog-front-end device 100 operates in the low-power mode, the phase-locked loop 130 is deactivated to reduce power consumption, and the functional circuit 10 keeps generating the analog signal ANA.

According to other embodiments of the present invention, when the analog-front-end device 100 operates in an access mode, the controller 150 of the analog-front-end device 100 executes the method 200 to activate and deactivate the phase-locked loop 130. According to yet another embodiment of the present invention, when the analog-front-end device 100 operates in a sampling mode, the controller 150 executes Steps S210-S230 to activate the phase-locked loop 130, and executes Steps S280-S290 to deactivate the phase-locked loop 130.

According to an embodiment of the present invention, when the analog-front-end device 110 operates in the sampling mode, the analog-front-end device 100 converts the analog signal ANA into the first data RDT based on the clock signal CLK. According to another embodiment of the present invention, when the analog-front-end device 100 operates in the access mode, the host 20 accesses the first data RDT stored in the first register 120. The sampling mode and the access mode will be described in the following paragraphs.

In Step S210, the controller 150 determines whether the flag F stored in the second register 140 is set to a first level. According to some embodiments of the present invention, since the flag F is configured to indicate whether the phase-locked loop 130 is activated, the controller 150 determines whether the phase-locked loop 130 is activated by determining whether the flag F is set to a first level. When the flag F is set to a first level, it indicates that the phase-locked loop 130 is activated. When the flag F is set to a second level, it indicates that the phase-locked loop 130 is deactivated.

When the controller 150 determines that the flag F is not set to a first level in Step S210, the controller 150 triggers the clock enable signal ENC to activate the phase-locked loop 130 to generate the clock signal CLK (Step S220), and also sets the flag F to the first level (Step S230). After the clock signal CLK is generated, the first register 120 is accessed with the clock signal CLK (Step S240).

According to some embodiments of the present invention, the first data RDT related to the analog signal ANA generated by the functional circuit 10 may be written into the first register 120 with the clock signal CLK. According to other embodiments of the present invention, the first data RDT stored in the first register 120 may be read with the clock signal CLK, which will be described in the following paragraphs.

The controller 150 further determines whether the first register 120 is idle (Step S250). When the controller 150 determines in Step S250 that the first register 120 is idle, the controller 150 triggers the idle signal SID to trigger the timer 160 to count the delay time (Step S260). When the controller 150 determines in Step S250 that the first register 120 is not idle, the controller 150 returns to Step S240 to access the first register 120.

After Step S260, it is determined whether the delay time counted by the timer 160 has reached the predetermined period (Step S270). According to an embodiment of the present invention, when it is determined in Step S260 that the delay time has not reached the predetermined period, the controller 150 returns to Step S260 and the timer 160 still counts the delay time. According to another embodiment of the present invention, when it is determined in Step S270 that the delay time has reached the predetermined period, the timer 160 triggers the clock disable signal DEN to deactivate the phase-locked loop 130 (Step S280).

According to some embodiments of the present invention, the timer 160 may be incorporated into the controller 150. In other words, the controller 150 counts the delay time, and triggers the clock disable signal DEN to deactivate the phase-locked loop 130 when the delay time reaches the predetermined period.

Referring to FIG. 2, when the phase-locked loop 130 is deactivated in Step S280, the controller 150 further sets the flag F to the second level (Step S290). According to some embodiments of the present invention, the flag F being set to a second level indicates that the phase-locked loop 130 is deactivated.

Referring to FIG. 1, the analog-front-end circuit 100 further includes an interface 170. According to some embodiments of the present invention, the analog-front-end circuit 100 communicates with a host 20 through the interface 170. According to some embodiments of the present invention, the controller 150 receives a first instruction INS1 from the host 20 through the interface 180 to operate in sampling mode. When the controller 150 operates in the sampling mode, the controller 150 activates the phase-locked loop 130 to generate the clock signal CLK, and activates the analog-to-digital converter 110 by using the conversion signal ENV to convert the analog signal ANA to the first data RDT based on the clock signal CLK. According to some embodiments of the present invention, the host 20 may be a MCU.

According to other embodiments of the present invention, the controller 150 receives a second instruction INS2 from the host 20 through the interface 180 to operate in an access mode. When the controller 150 operates in the access mode, the controller 150 activates the phase-locked loop 130 to generate the clock signal CLK, so that the first data RDT stored in the first register 120 is provided to the host 20 through the interface 170. The sampling mode and the access mode will be further described in the following paragraphs.

FIG. 3 illustrates operations of an analog-front-end circuit in accordance with an embodiment of the present invention. In the following paragraphs, FIG. 3 will be described in accompanied with the analog-front-end circuit 100 in FIG. 1.

As shown in FIG. 3, the pulse repetition period TPRP includes the sampling mode MS, the low-power mode MLP, and the access mode MA, and the pulse repetition period TPRP is repeated one after another. In other words, the analog-front-end device 100 in FIG. 1 operates in the sampling mode MS every the pulse repetition period TPRP. After the sampling mode MS, the analog-front-end device 100 operates in the low-power mode MLP, thereby greatly reducing the overall power consumption.

Namely, the analog-front-end device 100 periodically operates in the sampling mode MS to store the first data RDT generated by the analog-to-digital converter 110 in the first register 120, and occasionally operates in the access mode MA to transmit the first data RDT in the first register 120 to the host 20. According to an embodiment of the present invention, the controller 150 of the analog-front-end device 100 executes the method 200 in FIG. 2, or part of the method 200, to activate the phase-locked loop 130 during the sampling mode MS or the access mode MA.

According to another embodiment of the present invention, the controller 150 activates the phase-locked loop 130 before the sampling mode MS or the access mode MA, so that the clock signal CLK is steady during the sampling mode MS and the access mode MA. In other words, the clock signal CLK should be steady before the analog-to-digital converter 110 converts the analog signal ANA or the first register 120 is accessed.

As shown in FIG. 3, the access mode MA is occasionally occurred during the period of the low-power mode MLP. More specifically, the timing of the access mode MA depends on whenever the host 20 transmits the second instruction INS2. Namely, the timing of the access mode MA is unpredictable. According to some embodiments of the present invention, the access mode MA may not be overlapped with the sampling mode MS. According to other embodiments of the present invention, the access mode MA may be overlapped with sampling mode MS. In the embodiment of FIG. 3, the access mode MA is not overlapped with the sampling mode MS.

According to some embodiments of the present invention, the pulse repetition period TPRP and the sampling period TSA are defined in the first instruction INS1. According to some embodiments of the present invention, the first instruction INS1 may be a driver of the analog-front-end device 100. Once the first instruction INS1 is provided to the analog-front-end device 100, the behavior of the analog-front-end device 100 has been specified. According to some embodiments of the present invention, the analog-front-end device 100 issues an interrupt to the host 20, and the host 20 sends the second instruction INS2 to read the first data RDT in the first register 120.

As shown in FIG. 3, when the pulse repetition period TPRP and the sampling period TSA are defined in the first instruction INS1, the period of the low-power mode MLP is also specified. Less a duty ratio of the sampling period TSA to the pulse repetition period TPRP is, lower power consumption of the analog-front-end device 100 is consumed.

In addition, once the first instruction INS1 is provided to the analog-front-end device 100, it is unnecessary for the host 20 to control the analog-front-end device 100. As shown in FIG. 2, the controller 150 executes the method 200 to activate/deactivate the phase-locked loop 130 without a control from the host 20. The resources of the host 20 and the communication channels can be preserved for other applications.

Analog-front-end devices and methods thereof are provided herein. The analog-front-end devices provided herein are able to wake up from the low-power mode to the sampling mode or the access mode by using the methods provided herein. In addition, the analog-front-end devices are also able to return to the low-power mode when the sampling mode or the access mode is completed. Moreover, a flag indicating whether the phase-locked loop is activated is provided. It is much convenient for the analog-front-end devices to determine whether the phase-locked loop is activated by monitoring the flag.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be devel-oped, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An analog-front-end device, comprising:
a phase-locked loop, being activated based on a clock enable signal to generate a clock signal;
a first register, storing first data related to an analog signal based on the clock signal;
an analog-to-digital converter, retrieving setting parameters from the first register based on the clock signal and converting the analog signal to the first data based on the clock signal; and
a controller, determining whether the phase-locked loop is activated based on a flag to generate the clock enable signal and operating in a sampling mode based on a first instruction;
wherein when the controller operates in the sampling mode, the controller activates the phase-locked loop using the clock enable signal;
wherein when the controller exits the sampling mode, the controller deactivates the phase-locked loop.

2. The electronic circuit as claimed in claim 1, further comprising:
a second register, storing the flag indicating whether the phase-locked loop is activated;
wherein when the flag is set to a first level, the phase-locked loop is activated;
wherein when the flag is set to a second level, the phase-locked loop is deactivated.

3. The analog-front-end device as defined in claim 2, wherein before the controller activates the phase-locked loop, the controller determines whether the phase-locked loop is activated by determining whether the flag is set to a first level.

4. The analog-front-end device as defined in claim 2, further comprising:
a timer, counting a delay time based on an idle signal and generating a clock disable signal when the delay time reaches a predetermined period;
wherein when the first register is idle, the controller enables the idle signal to trigger the timer to count the delay time;
wherein when the delay time reaches the predetermined period, the timer triggers the clock disable signal to deactivate the phase-locked loop and to set the flag to the second level.

5. The analog-front-end device as defined in claim 4, wherein the setting parameters comprise a pulse repetition period, a sampling period of the sampling mode, offset error, full-scale error, differential nonlinearity (DNL), and integral nonlinearity (INL);
wherein the pulse repetition period comprises a low-power mode and the sampling mode.

6. The analog-front-end device as defined in claim 4, further comprising:
an interface, receiving the first instruction from a host;
wherein when the interface receives the first instruction, the interface provides the first instruction to the controller.

7. The analog-front-end device as defined in claim 6, wherein when the host transmits a second instruction to access the first data in the first register, the controller operates in an access mode;
wherein when the controller operates in the access mode, the controller activates the phase-locked loop;
wherein before the phase-locked loop is activated, the controller checks the flag to determine whether the phase-locked loop is deactivated;
wherein when the flag indicates that the phase-locked loop is deactivated, the controller activates the phase-locked loop;
wherein the first data in the first register and the clock signal are provided to the host through the interface.

8. The analog-front-end device as defined in claim 7, wherein the controller periodically operates in the sampling mode, and occasionally operates in the access mode based on the second instruction being received.

9. The analog-front-end device as defined in claim 7, wherein the first instruction defines a pulse repetition period and a duty period of the sampling mode in the pulse repetition period;
wherein when the controller does not operate the sampling mode during the pulse repetition period, the analog-front-end device operates in a low-power mode to minimize power consumption.

10. The analog-front-end device as defined in claim 9, wherein the access mode occurs when the controller does not operate in the sampling mode.

11. A method for accessing a first register of an analog-front-end device operating in a low-power mode, wherein the analog-front-end device further comprises a phase-locked loop generating a clock signal, wherein the method comprises:
determining whether a flag is set to a first level;
when the flag is not set to a first level, activating the phase-locked loop to generate the clock signal; and
accessing the first register based on the clock signal.

12. The method as claimed in claim 11, further comprising:
when the flag is set to a first level, determining that the phase-locked loop is activated; and
when the flag is not set to a first level, determining that the phase-locked loop is deactivated and then activating the phase-locked loop.

13. The method as claimed in claim 11, further comprising:
determining whether the first register is idle;
when the first register is idle, counting a delay time;
determining whether the delay time has reached a predetermined period;
when the delay time reaches the predetermined period, deactivating the phase-locked loop and setting the flag to the second level; and
when the delay time has not reached the predetermined period, keeping the phase-locked loop activated and continuing to count the delay time.

14. The method as claimed in claim 11, wherein the analog-front-end device further comprises an interface, wherein the method further comprises:
receiving a first instruction from a host through the interface;
operating in a sampling mode;
activating the phase-locked loop to generate the clock signal in the sampling mode; and
after the sampling mode, deactivating the phase-locked loop and the functional circuit;
wherein the step of accessing the first register based on the clock signal further comprises:
writing first data related to the analog signal into the first register based on the clock signal.

15. The method as claimed in claim 14, wherein the analog signal is converted into the first data by an analog-to-digital converter;
wherein the first data is digital data;
wherein setting parameters of the analog-to-digital converter are stored in the first register;
wherein the setting parameters comprise a pulse repetition period, a sampling period of the sampling mode, offset error, full-scale error, differential nonlinearity (DNL), and integral nonlinearity (INL);
wherein the pulse repetition period comprises a low-power mode and the sampling mode.

16. The method as claimed in claim 15, wherein the period of the sampling mode is defined in the first instruction.

17. The method as claimed in claim 14, further comprising:
receiving a second instruction from the host through the interface;
operating in an access mode based on the second instruction;
activating the phase-locked loop to generate the clock signal in the access mode;
providing the first data from the first register to the host through the interface; and
after the access mode, deactivating the phase-locked loop and the functional circuit;
wherein the step of accessing the first register based on the clock signal further comprises:
reading the first data in the first register based on the clock signal.

18. The method as claimed in claim 17, wherein the sampling mode is operated periodically, and the access mode is operated occasionally based on the second instruction being received.

19. The method as claimed in claim 17, wherein the first instruction defines a pulse repetition period;
wherein the analog-front-end device is operated in either the sampling mode or the low-power mode during the pulse repetition period;
wherein a duty period of the sampling mode is defined in the first instruction.

20. The method as claimed in claim 19, wherein the analog-front-end device is operated in the access mode when the analog-front-end device is not operated in the sampling mode.
